(19) United States
(12) Patent Application Publication
(10) Pub. No.: US 2026/0082787 A1
(43) Pub. Date: Mar. 19, 2026

(54) DISPLAY PANEL AND ELECTRONIC DEVICE HAVING THE SAME

(71) Applicant: SAMSUNG DISPLAY CO., LTD., Yongin-si (KR)

(72) Inventors: SEONGBAIK CHU, Yongin-si (KR); YOUNGWOO PARK, Yongin-si (KR); TAESIK KIM, Yongin-si (KR); JINA LEE, Yongin-si (KR); HYUNWOOK LEE, Yongin-si (KR)

(21) Appl. No.: 19/323,073

(22) Filed: Sep. 9, 2025

(30) Foreign Application Priority Data
Sep. 13, 2024 (KR) 10-2024-0125433

(51) Int. Cl. H10K 59/131; H10K 59/124; H10K 102/00

(52) U.S. Cl. CPC H10K 59/1315; H10K 59/124; H10K 2102/341

(57) ABSTRACT

A display panel includes: a base member; a plurality of pixels; a plurality of first lines configured to transfer an electrical signal to the plurality of pixels; a first insulating layer covering the plurality of first lines; a second line disposed on the first insulating layer; a second insulating layer disposed on the first insulating layer and covering the second line; a plurality of third lines disposed on the second insulating layer, wherein at least one of the plurality of third lines overlaps with the plurality of first lines; a third insulating layer covering the plurality of third lines; and a connection line overlapping with the at least one of the plurality of third lines, wherein the connection line is configured to electrically connect a portion of the plurality of first lines and the second line to each other.

### CROSS-REFERENCE TO RELATED APPLICATION

This application claims priority under 35 U.S.C. § 119 to Korean Patent Application No. 10-2024-0125433, filed on Sep. 13, 2024, in the Korean Intellectual Property Office, the disclosure of which is incorporated by reference herein in its entirety.

### TECHNICAL FIELD

The present invention relates to a display panel with decreased defectiveness due to a residual film and an electronic device including the same.

### DISCUSSION OF THE RELATED ART

As an information age approaches, an electronic device is under development with a new technology for meeting various needs of a consumer. Among those technologies, development is being focused on a display device with high resolution and a clear image.

To increase resolution of a display device, titanium (Ti) and aluminum (Al) may be used to reduce resistance between wires adjacent to a portion of spider wires disposed below a bottom portion of a conventional display panel, thereby reducing power consumption.

However, unlike a wire that includes molybdenum (Mo), a wire including titanium (Ti) and aluminum (Al) may have a greater thickness. This may prevent an angle, which is between a bottom base member and a starting point of an electrode pattern, from being decreased. Due to such a property, this thickness variation may create a level difference in areas where a wire including titanium (Ti) and aluminum (Al) is used, and it may become difficult to process a full etching during a process.

In addition, there may be a problem where a wire using titanium (Ti) and aluminum (Al) is not entirely removed during the etching process, potentially allowing a short-circuit current to flow through a display panel, leading to defects.

### SUMMARY

An object of the present disclosure is to provide a display panel with reduced defective rate due to a residual film and an electronic device including the same.

A display panel according to an embodiment of the present disclosure may include a base member defined with a first region and a second region surrounding the first region. A plurality of pixels may be disposed on the first region. A plurality of first lines may be disposed on the second region and configured to transfer an electrical signal to the plurality of pixels, each extending in a pre-determined direction. A first insulating layer may cover the plurality of first lines. A second line may be disposed on the first insulating layer. A second insulating layer may be disposed on the first insulating layer and cover the second line. A plurality of third lines may be disposed on the second insulating layer, each extending in a direction intersecting with the pre-determined direction. At least one of the plurality of third lines may overlap with the plurality of first lines. A third insulating layer may be disposed on the second insulating layer and cover the plurality of third lines. A connection line may extend in the pre-determined direction, overlap with at least one of the plurality of third lines and be configured to electrically connect a portion of the plurality of first lines to the second line.

In an embodiment of the present disclosure, each of the plurality of first lines may have a first thickness and the second line may have a second thickness that is greater than the first thickness.

In an embodiment of the present disclosure, each of the plurality of first lines may include a first metallic material, and the second line may include a second metallic material that is different from the first metallic material.

In an embodiment of the present disclosure, the first metallic material may include molybdenum (Mo), and the second metallic material may include at least one of titanium (Ti) and aluminum (Al).

In an embodiment of the present disclosure, the connection line may be disposed on the first insulating layer.

In an embodiment of the present disclosure, a first contact hole, a second contact hole, a third contact hole and a fourth contact hole may be defined on the second insulating layer. The first contact hole may overlap with any one of the plurality of third lines and the portion of the plurality of first lines. The second contact hole may overlap with the one of the plurality of third lines and the connection line. The third contact hole may overlap with another of the plurality of third lines and the connection line. The fourth contact hole may overlap with the other of the plurality of third lines and the second line.

In an embodiment of the present disclosure, a first contact hole, a second contact hole and a third contact hole may be defined on the second insulating layer. The connection line may make contact with the portion of the plurality of first lines. The first contact hole may overlap with any one of the plurality of third lines. The first contact hole may overlap with the connection line or the portion of the plurality of first lines. The second contact hole may overlap with another of the plurality of third lines and the connection line. The third contact hole may overlap with the other of the plurality of third lines and the second line.

In an embodiment of the present disclosure, the connection line may be disposed on the third insulating layer.

In an embodiment of the present disclosure, a first contact hole and a second contact hole may be defined on the second insulating layer, and a third contact hole and a fourth contact hole may be defined on the third insulating layer. The first contact hole may overlap with any one of the plurality of third lines and the portion of the plurality of first lines. The second contact hole may overlap with any one of the plurality of third lines and the second line. The third contact hole may overlap with the connection line and the one of the plurality of third lines. The fourth contact hole may overlap with the connection line and the other of the plurality of third lines.

In an embodiment of the present disclosure, a data driving circuit may be disposed on the second region. The display panel may be configured to receive a data signal from the data driving circuit and provide the data signal to the plurality of pixels and include a demultiplexer interposed between the data driving circuit and the first region on a plane. At least one of the plurality of first lines, the second line, the plurality of third lines and the connection line may be interposed between the data driving circuit and the demultiplexer on the plane.

In an embodiment of the present disclosure, an angle between a segment corresponding to a side of the second line and a normal line of the base member in a cross-sectional plane may be less than an angle between a segment corresponding to a side of each of the plurality of first lines and the normal line.

In an embodiment of the present disclosure, the electronic device may include a base member. A semiconductor pattern may be disposed on the base member. A first gate insulating layer may be disposed on the semiconductor pattern. A gate electrode pattern may be disposed on the first gate insulating layer and have at least a portion overlapping with the semiconductor pattern. A second gate insulating layer may be disposed on the first gate electrode pattern. A second electrode pattern may be disposed on the second gate insulating layer. A third gate insulating layer may be disposed on the second gate electrode pattern. A third gate electrode pattern may be disposed on the third gate insulating layer and have a greater thickness than the second gate electrode pattern. An interlayer insulating layer may be disposed on the gate electrode pattern. A first source-drain electrode pattern may be disposed on the interlayer insulating layer. A first via insulating layer may be disposed on the first source-drain electrode pattern. The second source-drain electrode pattern may be disposed on the first via insulating layer. The second gate electrode pattern may include a plurality of first lines, of which each extends in a pre-determined direction. The third gate electrode pattern may include a second line. The first source-drain electrode pattern may have at least one including a plurality of third lines configured to electrically connect two nonadjacent first lines to each other among the plurality of first lines. One of the second gate electrode pattern and the second source-drain electrode pattern may include a connection line extending in the pre-determined direction. The connection line may overlap with at least one of the plurality of third lines and be configured to electrically connect a portion of the plurality of first lines and the second line.

In an embodiment of the present disclosure, a second via insulating layer may be disposed on the second source-drain electrode pattern. The electronic device may further include a light-emitting diode disposed on the second via insulating layer and including an anode electrode, a light-emitting layer and a cathode electrode.

In an embodiment of the present disclosure, the second gate electrode pattern may include molybdenum (Mo), and the third gate electrode pattern may include at least one of titanium (Ti) and aluminum (Al).

In an embodiment of the present disclosure, a first tangent line may be defined to extend from an intersection point of the second gate electrode pattern on a plane parallel to the base member, and a second tangent line may be defined to extend from an intersection point of the third gate electrode pattern on a plane parallel to the base member. A slope of the first tangent line may be less than a slope of the second tangent line.

In an embodiment of the present disclosure, the connection line may be disposed below the third gate insulating layer.

In an embodiment of the present disclosure, a first contact hole, a second contact hole, a third contact hole and a fourth contact hole may be defined on the interlayer insulating layer. The first contact hole may overlap with any one of the plurality of third lines and the portion of the plurality of first lines, and the second contact hole may overlap with any one of the plurality of third lines and the connection line, the third contact hole may overlap with another of the plurality of third lines and the connection line, and the fourth contact hole may overlap with the other of the plurality of third lines and the second line.

In an embodiment of the present disclosure, a first contact hole, a second contact hole and a third contact hole may be defined on the interlayer insulating layer. The connection line may overlap with the portion of the plurality of first lines, the first contact hole may overlap with any one of the plurality of third lines, the first contact hole may overlap with the connection line or the portion of the plurality of first lines, the second contact hole may overlap with another of the plurality of third lines and the connection line, and the third contact hole may overlap with the other of the plurality of third lines and the second line.

In an embodiment of the present disclosure, the connection line may be disposed on the first via insulating layer.

In an embodiment of the present disclosure, a first contact hole and a second contact hole may be defined on the interlayer insulating layer, and a third contact hole and a fourth contact hole may be defined on the first via insulating layer. The first contact hole may overlap with any one of the plurality of third lines and the portion of the plurality of first lines, the second contact hole may overlap with another of the plurality of third lines and the second line, the third contact hole may overlap with the one of the plurality of third lines and the connection line, and the fourth contact hole may overlap with the other of the plurality of third lines and the connection line.

According to an embodiment of the present disclosure, it becomes possible to provide a display panel with reduced defective rate due to a residual film and an electronic device including the same.

### BRIEF DESCRIPTION OF THE DRAWINGS

The above and other aspects and features of embodiments of the present invention will be more apparent by describing in detail embodiments thereof, with reference to the accompanying drawings, in which:

FIG. 1 is a perspective view of an electronic device according to an embodiment of the present invention;

FIG. 2 is an exploded view of an electronic device according to an embodiment of the present invention;

FIG. 3 is a plan view of a display panel according to an embodiment of the present invention;

FIG. 4 is an illustration of an equivalent circuit of a pixel according to an embodiment of the present invention;

FIG. 5 is an illustration of signals applied to a pixel shown in FIG. 4;

FIG. 6 is an illustration of a cross-section of a display panel according to an embodiment of the present invention;

FIG. 7 is an illustration of a layout corresponding to a section marked with AA shown in FIG. 3;

FIG. 8A is an illustration of a portion of a cross-section taken along the line I-I′ shown in FIG. 7;

FIG. 8B is an illustration of a portion of a cross-section taken along the line II-II′ shown in FIG. 7;

FIG. 9A is an illustration of a layout of a plurality of first lines and a connection line in the second gate electrode pattern shown in FIG. 7;

FIG. 9B is an illustration with an addition of a plurality of second lines to FIG. 9A;

FIG. 9C is an illustration with an addition of a plurality of third lines to FIG. 9B;

FIG. 9D is an illustration of a portion of a cross-section taken along the line III-III′ shown in FIG. 7;

FIG. 10A is an illustration of an embodiment of a layout corresponding to a section marked with AA shown in FIG. 3;

FIG. 10B is an illustration of a layout of a plurality of first lines in a second gate electrode pattern;

FIG. 10C is an illustration with an addition of a plurality of second lines to FIG. 10B;

FIG. 10D is an illustration with an addition of a plurality of third lines to FIG. 10C;

FIG. 10E is an illustration of a portion of a cross-section taken along the line IV-IV′ shown in FIG. 10A;

FIG. 11A is an illustration of a layout corresponding to a section marked with AA shown in FIG. 3, according to an embodiment of the present invention;

FIG. 11B is an illustration of a layout of a plurality of first lines in a second gate electrode pattern;

FIG. 11C is an illustration with an addition of a layout of a plurality of second lines to FIG. 11B;

FIG. 11D is an illustration with an addition of a layout of a plurality of third lines to FIG. 11C;

FIG. 11E is an illustration with an addition of a layout of a connection line to FIG. 11D; and FIG. 11F is an illustration of a portion of a cross-section taken along the line V-V′ shown in FIG. 11A.

FIG. 12 is a block diagram of an electronic device according to an embodiment of the present invention.

FIG. 13 illustrates schematic diagrams of electronic devices according to embodiments of the present invention.

### DETAILED DESCRIPTION OF THE EMBODIMENTS

Embodiments of the present invention will now be described more fully with reference to the accompanying drawings. It is to be understood that the present invention may be embodied in different forms and thus should not be construed as being limited to the embodiments set forth herein. It is to be understood that like reference numerals may refer to like elements throughout the specification, and thus, redundant descriptions may be omitted.

Unless otherwise defined, all terms, including technical terms and scientific terms, used herein have the same meaning as how they are generally understood by those of ordinary skill in the art to which the present disclosure pertains. Any term that is defined in a general dictionary shall be construed to have the same meaning in the context of the relevant art, and, unless otherwise defined explicitly, shall not be interpreted to have an idealistic or excessively formalistic meaning.

Embodiments of the present invention relate to a display panel and an electronic device incorporating the panel, designed to improve manufacturing efficiency and display performance. Traditional display panels face challenges related to residual metallic films that remain after the etching process, leading to potential defects such as short circuits and increased power consumption. To address these issues, the present invention introduces a multi-layered wiring structure to increase etching precision and electrical connectivity within the panel.

Embodiments of the present invention is the use of different metallic materials for the gate electrode patterns. A second gate electrode pattern may include molybdenum (Mo), while a third gate electrode pattern may include titanium (Ti) and aluminum (Al). This material selection reduces resistance between adjacent wires but also introduces fabrication challenges due to differences in etching characteristics. To mitigate this, embodiments of the present invention defines layer thicknesses and sidewall angles to ensure that undesired residual metallic materials are minimized, thus preventing electrical defects in the display panel.

Embodiments of the present invention further improves signal transmission within the display panel through a wiring and contact hole structure. By incorporating multiple conductive layers, including first, second, and third lines, and strategically placing contact holes, the display panel may achieve efficient electrical connectivity while maintaining structural integrity.

FIG. 1 is a perspective view of an electronic device ED according to an embodiment of the present invention.

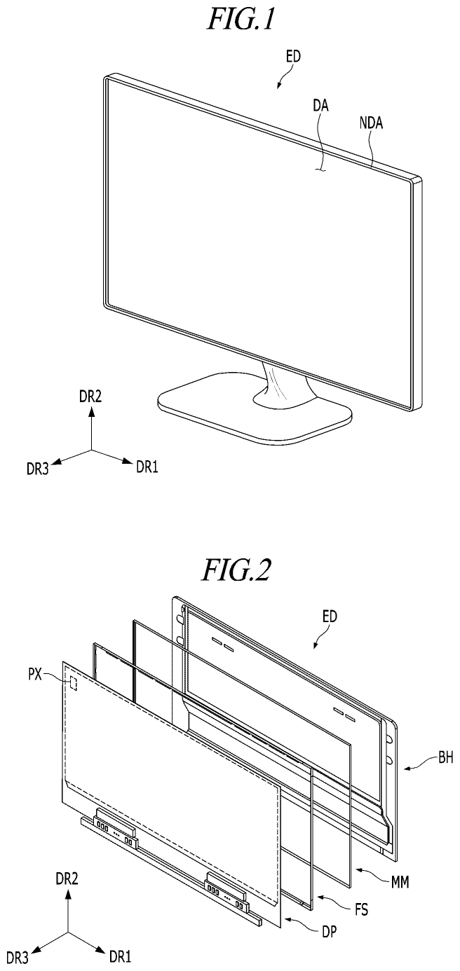

FIG. 2 is an exploded view of an electronic device ED according to an embodiment of the present invention.

A first through third directions DR1, DR2 and DR3 may be defined. The first direction DR1 and the second direction DR2 may be directions defined on a plane of the electronic device ED shown in FIG. 1. In addition, the first direction DR1 and the second direction DR2 may intersect each other. The third direction DR3 may be a thickness direction of the electronic device ED shown in FIG. 1. For example, the third direction DR3 may be perpendicular to the first and second directions DR1 and DR2.

According to an embodiment of the present invention, FIG. 1 illustrates an electronic device ED that includes a display device. For example, the display device may be incorporated into the electronic device ED. The display device may be a device configured to display an image and may be incorporated into electronic device ED, such as a monitor, a television, a smartphone, a wearable device, a navigation, a terminal mounted on a vehicle or a tablet. A shape and a function are not limited thereto. For example, a front face may be various shapes, such as a circle or a polygon. In addition, the display device may have a curved shape curved to a specific direction instead of a plane.

Referring to FIG. 2, an electronic device ED may include a display panel DP, a front chassis FS, a middle mold MM and a rear housing BH. In addition, a plurality of pixels PX may be included in a display panel DP. Furthermore, the electronic device ED may be manufactured by disposing the display panel DP in an opening that is provided in the front chassis FS, coupling the display panel DP to the middle mold MM, and subsequently coupling the middle mold MM to the rear housing BH.

The display panel DP, which is configured to display an image in the electronic device ED, may be exposed in front of the electronic device ED so that a user may view the image. In addition, a plurality of pixels PX may be disposed in the display panel DP, and an image may be provided on the display panel DP through an operation of each of the pixels PX.

An opening part may be defined in front of the front chassis FS, and the display panel DP may be disposed on the opening part. Accordingly, with no additional elements blocking a front surface of the display panel DP, the bezel of the display device DD may be minimized.

The middle mold MM may have a portion coupled to a rear surface of the display panel DP and another portion coupled to the front chassis FS. Accordingly, the display panel DP disposed in front of the front chassis FS may be fixed.

A rear housing BH may be coupled to the middle mold MM. In addition, the rear housing BH may be provided with a plate shape so that the display panel DP may be protected, for example, from external impact. In addition, the rear housing BH may include an exhaust vent to dissipate internal heat from the electronic device ED to an external environment.

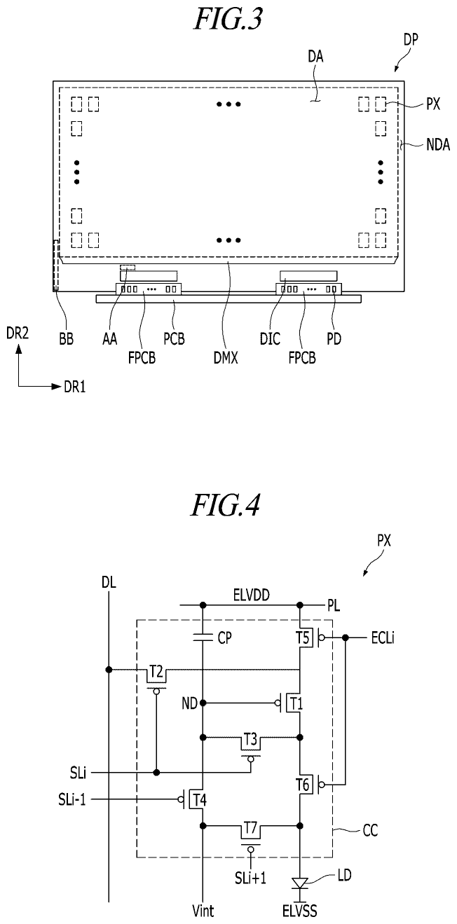

FIG. 3 is an illustration of a plan view of a display panel DP according to an embodiment of the present invention.

A display region DA and a non-display region NDA may be defined on a display panel DP. The non-display region NDA may at least partially surround the display region DA. A plurality of pixels PX may be disposed to overlap with the display region DA. The plurality of pixels PX may be disposed with a specific arrangement on the display panel DP. For example, the plurality of pixels PX may be repeatedly disposed in a first direction DR1, and the plurality of pixels PX repeatedly disposed in a first direction DR1 may be repeatedly disposed in a second direction DR2. Eventually, the plurality of pixels PX may be disposed in a matrix shape. In addition, each of the plurality of pixels PX may display a different color on the display panel DP. The display panel DP may include a demultiplexer DMX, a data driving circuit DIC, a flexible printed circuit board FPCB and signal pads PD. The demultiplexer DMX, the data driving circuit DIC, the flexible printed circuit board FPCB and the signal pads PD may be disposed on the non-display region NDA of the display panel DP.

The data driving circuit DIC may have an integrated circuit (IC) chip shape and be mounted on the display panel DP. The data driving circuit DIC may be an element configured to transfer a data signal to the pixel PX.

A data signal output from the data driving circuit DIC may be transferred to the demultiplexer DMX. The demultiplexer DMX may be configured to divide the received data output signal and provide the signal to the plurality of pixels PX.

The plurality of signal pads PD may be mounted on the flexible printed circuit board FPCB. According to an embodiment of the present disclosure, the plurality of signal pads PD may be electrically connected to the data driving circuit DIC to transfer a signal for operating the data driving circuit DIC.

In addition, a printed circuit board PCB may be mounted on the flexible printed circuit board FPCB. However, the present disclosure is not limited thereto, and the flexible printed circuit board FPCB may be electrically connected to the printed circuit board PCB through a separate part.

The section marked with AA shown in FIG. 3 may be defined to refer to a partial region of a wire between the demultiplexer DMX and the data driving circuit DIC.

The section marked with BB shown in FIG. 3 may refer to a bottom partial region of the non-display region NDA of the display panel DP.

According to an embodiment of the present disclosure, the wire in the section marked with BB shown in FIG. 3 may be equivalently applied as the wire in the section marked with AA shown in FIG. 3. Hereinafter, a shape of a wire is explained based on the section marked with AA.

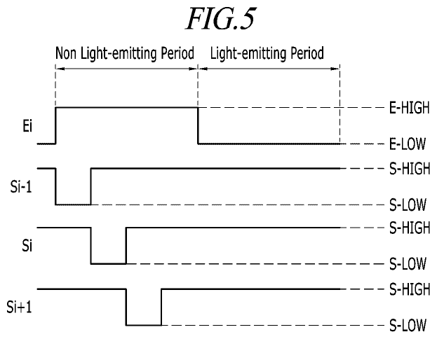

FIG. 4 is an illustration of an equivalent circuit of a pixel PX according to an embodiment of the present disclosure. FIG. 5 illustrates an example of an emission control signal Ei and scan signals Si−1, Si, Si+1 applied to a pixel PX of FIG. 4. FIG. 5 illustrates an example of a pixel PX connected to an i-th scan line SLi and an i-th emission control line ECLi.

The pixel PX may include a light-emitting diode LD and a pixel circuit CC.

In the present disclosure, an organic light emitting diode OLED is illustrated as a light-emitting diode LD, but the present disclosure is not limited thereto.

The pixel circuit CC may include a plurality of transistors T1 through T7 and a capacitor CP. The pixel circuit CC may be configured to respond to the data signal to control current flowing through the light-emitting diode LD.

The light-emitting diode LD may be configured to emit light at a predetermined luminance level based on the amount of current supplied by the pixel circuit CC. To achieve this, the first power level ELVDD is set higher than the second power level ELVSS.

Each of the plurality of transistors T1 to T7 may include an input electrode (or a source electrode), an output electrode (or a drain electrode), and a control electrode (or a gate electrode). In the present disclosure, for convenience, one of the input electrode and the output electrode may be referred to as a first electrode, and the other remaining electrode may be referred to as a second electrode.

The first electrode of the first transistor T1 is connected to the first power ELVDD via the fifth transistor T5, and the second electrode is connected to the anode electrode of the light-emitting diode LD via the sixth transistor T6. The first transistor T1 may be referred to as a driving transistor in this specification.

The first transistor T1 is configured to control the amount of current flowing through the light-emitting diode LD in response to a voltage applied to the control electrode.

The second transistor T2 is connected between the data line DL and the first electrode of the first transistor T1. In addition, the control electrode of the second transistor T2 is connected to the i-th scan line SLi. When the i-th scan signal Si is provided to the i-th scan line SLi, the second transistor T2 is turned on to electrically connect the data line DL and the first electrode of the first transistor T1.

The third transistor T3 is connected between the second electrode of the first transistor T1 and the control electrode. The control electrode of the third transistor T3 is connected to the i-th scan line SLi. When the i-th scan signal Si is provided to the i-th scan line SLi, the third transistor T3 is turned on to electrically connect the second electrode of the first transistor T1 and the control electrode. Accordingly, when the third transistor T3 is turned on, the first transistor T1 is connected in the form of a diode.

The fourth transistor T4 is connected between the node ND and an initialization power generation unit (not shown). In addition, the control electrode of the fourth transistor T4 is connected to the (i−1)-th scan line SLi−1 . When the (i−1)-th scan signal Si−1 is provided to the (i−1)-th scan line SLi−1 , the fourth transistor T4 is turned on to provide an initialization voltage Vint to the node ND.

The fifth transistor T5 is connected between a power line PL and the first electrode of the first transistor T1. The control electrode of the fifth transistor T5 is connected to the i-th light-emission control line ECLi.

The sixth transistor T6 is connected between the second electrode of the first transistor T1 and the anode electrode of the light-emitting diode LD. In addition, the control electrode of the sixth transistor T6 is connected to the i-th light-emission control line ECLi.

The seventh transistor T7 is connected between the initialization power generation unit (not shown) and the anode electrode of the light-emitting diode LD. In addition, the control electrode of the seventh transistor T7 is connected to the (i+1)-th scan line SLi+1. When the (i+1)-th scan signal Si+1 is provided to the (i+1)-th scan line SLi+1, such seventh transistor T7 is turned on to provide the initialization voltage Vint to the anode electrode of the light-emitting diode LD.

The seventh transistor T7 may improve the black expression capability of the pixel PX. Specifically, when the seventh transistor T7 is turned on, it discharges a parasitic capacitor of the light-emitting diode LD. As a result, when the black luminance is displayed, the light-emitting diode LD does not emit light preventing unintended emission caused by leakage current from the first transistor T1. This effectively increases the accuracy of black level expression..

Additionally, in FIG. 5, the control electrode of the seventh transistor T7 is shown to be connected to the (i+1)-th scan line SLi+1, but the present disclosure is not limited to this configuration. In another embodiment of the present disclosure, the control electrode of the seventh transistor T7 may be connected to the i-th scan line SLi or the (i−1)-th scan line SLi−1 .

FIG. 4 is Illustrated based on PMOS, but the present disclosure is not limited to this configuration. In another embodiment of the present disclosure, the pixel PX may be composed of NMOS. In another embodiment of the present disclosure, the pixel PX may be composed of a combination of NMOS and PMOS.

The capacitor CP is interposed between the power line PL and the node ND. The capacitor CP is configured to store a voltage corresponding to the data signal. When the fifth transistor T5 and the sixth transistor T6 are turned on, the amount of current flowing through the first transistor T1 may be determined according to the voltage stored in the capacitor CP.

Referring to FIG. 5, the light-emitting control signal Ei may have a high level E-HIGH or a low level E-LOW. Each of the scan signals SLi−1 , SLi, and SLi+1 may have a high level S-HIGH or a low level S-LOW.

When the light emission control signal Ei has a high level E-HIGH, the fifth transistor T5 and the sixth transistor T6 are turned off. When the fifth transistor T5 is turned off, the power line PL and the first electrode of the first transistor T1 are electrically cut off. When the sixth transistor T6 is turned off, the second electrode of the first transistor T1 and the anode electrode of the light-emitting diode LD are electrically cut off. Accordingly, the light-emitting diode LD does not emit light while the light emission control signal Ei having a high level E-HIGH is provided to the i-th light emission control line ECLi.

Thereafter, when the (i−1)-th scan signal Si−1 provided to the (i−1)-th scan line SLi−1 has a low level S-LOW, the fourth transistor T4 is turned on. When the fourth transistor T4 is turned on, the initialization voltage Vint is provided to the node ND.

When the i-th scan signal Si provided to the i-th scan line SLi has a low level S-LOW, the second transistor T2 and the third transistor T3 are turned on.

When the second transistor T2 is turned on, a data signal is provided to the first electrode of the first transistor T1. Here, since the node ND is initialized to the initialization voltage Vint, the first transistor T1 is turned on. When the first transistor T1 is turned on, a voltage corresponding to the data signal is provided to the node ND. Here, the capacitor CP stores a voltage corresponding to the data signal.

When the (i+1)-th scan signal Si+1 provided to the (i+1)-th scan line SLi+1 has a low level S-LOW, the seventh transistor T7 is turned on.

When the seventh transistor T7 is turned on, the initialization voltage Vint is provided to the anode electrode of the light-emitting diode LD, thereby discharging the parasitic capacitor of the light-emitting diode LD.

When the light emission control signal Ei provided to the light emission control line ECLi has a low level E-LOW, the fifth transistor T5 and the sixth transistor T6 are turned on. When the fifth transistor T5 is turned on, the first power ELVDD is provided to the first electrode of the first transistor T1. When the sixth transistor T6 is turned on, the second electrode of the first transistor T1 and the anode electrode of the light-emitting diode LD are electrically connected. Then, the light-emitting diode LD generates light of a predetermined luminance in response to the amount of supplied current.

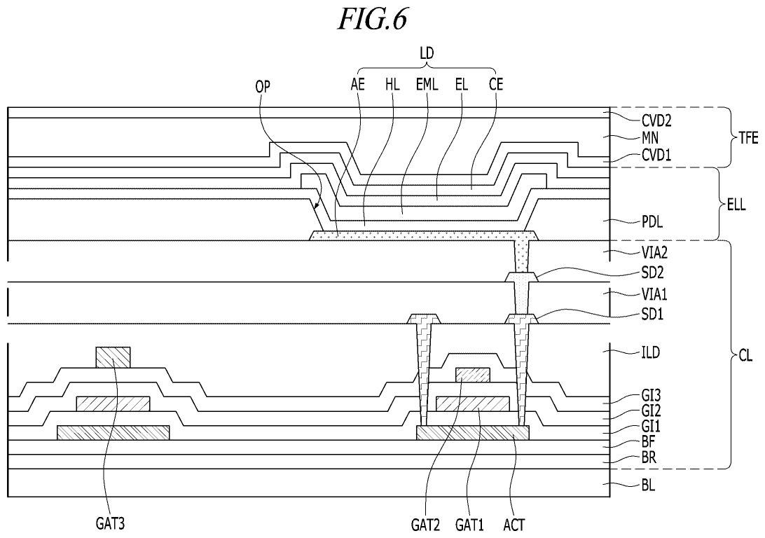

FIG. 6 is an illustration of a portion of a cross-section of a display panel DP according to an embodiment of the present invention.

The display panel DP may include a base member BL, a circuit layer CL, a light-emitting layer ELL and an encapsulation layer TFE.

The base member BL may include at least one of an organic material, an inorganic material and glass. The base member BL may include a first region and a second region at least partially surrounding the first region. A plurality of pixels PX may be disposed on the first region of the base member BL. The first region of the base member BL may correspond to the display region DA of the display panel DP. The second region of the base member BL may correspond to the non-display region NDA of the display panel DP.

The circuit layer CL may be disposed on the base member BL. The circuit layer CL may include a barrier layer BR, a buffer layer BF, a semiconductor pattern ACT, gate insulating layers GI1, GI2 and GI3, gate electrode patterns GAT1, GAT2 and GAT3, an interlayer insulating layer ILD, source-drain electrode patterns SD1 and SD2, and via insulating layers VIA1 and VIA2. A portion of the semiconductor pattern ACT may be an active unit of a transistor T1, a portion of the gate electrode patterns GAT1, GAT2 and GAT3 may be a control electrode of the transistor T1, and a portion of the source-drain electrode patterns SD1 and SD2 may be an input electrode and an output electrode of the transistor T1.

The light-emitting layer ELL may be disposed on the circuit layer CL. The light-emitting layer ELL may include a light-emitting diode LD and a pixel defining film PDL.

The encapsulation layer TFE may be configured to seal off and cover the light-emitting layer ELL to protect the light-emitting layer ELL from external oxygen and/or moisture.

The encapsulation layer TFE may include a first inorganic layer CVD1, an organic layer MN and a second inorganic layer CVD2. In FIG. 6, the encapsulation layer TFE is illustrated, as an example, to include two inorganic layers and one organic layer, but the present invention is not limited to this example. For example, the encapsulation layer TFE may include three inorganic layers and two organic layers, and in this case, the inorganic layers and the organic layers may be alternately laminated. A functional layer BR and BF may be disposed on one side of the base member BL. The functional layer BR and BF may include a barrier layer BR and a buffer layer BF.

The functional layer BR and BF may be configured to prevent an impurity existing at a bottom of the base layer BL from diffusing into a pixel during a manufacturing process. Particularly, the functional layer BR and BF may be configured to prevent impurities from spreading to a semiconductor pattern ACT that is connected to a pixel.

The semiconductor pattern ACT composing a transistor is disposed on the buffer layer BF. The semiconductor pattern ACT may include, for example, poly silicon or amorphous silicon. Other than the above, for example, the semiconductor pattern ACT may include a metallic oxide semiconductor. In an embodiment of the present invention, a thickness of the semiconductor pattern ACT may be about 470 Å, but the present invention is not limited thereto. The semiconductor pattern ACT may include a channel area that serves as a conduction passage for electron or hole movement, with a first ion-doped area and a second ion-doped area disposed on either side of the channel area.

A first gate insulating layer GI1 covering the active pattern ACT may be disposed on the buffer layer BF. The first gate insulating layer GI1 may include, for example, a silicon dioxide or a silicon nitride compound. In an embodiment of the present invention, a thickness of a first gate insulating layer GI1 may be about 1600 Å, but the present invention is not limited thereto.

A first gate electrode GAT1 may be disposed on the first gate insulating layer GI1. The first gate insulating pattern GAT1 may include molybdenum (Mo). In an embodiment of the present invention, a thickness of the first gate electrode pattern GAT1 may be about 3,000 Å, but the present invention is not limited thereto.

A second gate insulating layer GI2 covering the first gate electrode GAT1 may be disposed on the first gate insulating layer GI1. The second gate insulating layer GI2 may include, for example, a silicon nitride compound. In an embodiment of the present invention, a thickness of the second gate insulating layer GI2 may be about 1,400 Å, but the present invention is not limited thereto.

A second gate electrode GAT2 may be disposed on the second gate insulating layer GI2. The second gate electrode pattern GAT2 may include molybdenum (Mo). In an embodiment of the present invention, a thickness of the second gate electrode pattern GAT2 may be about 3,000 Å, but the present invention is not limited thereto.

A third gate insulating layer GI3 covering the second gate electrode pattern GAT2 may be disposed on the second gate insulating layer GI2. The third gate insulating layer GI3 may include, for example, a silicon nitride compound. In an embodiment of the present invention, a thickness of the third gate insulating layer GI3 may be about 1,400 Å, but the present invention is not limited thereto. In the present disclosure, the third gate insulating layer GI3 may be referred as a first insulating layer.

A third gate electrode pattern GAT3 may be disposed on the third gate insulating layer GI3. The third gate electrode pattern GAT3 may include at least one of titanium (Ti) or aluminum (Al). In an embodiment of the present invention, a thickness of the third gate electrode pattern GAT3 may be about 3800 Å, but the present invention is not limited thereto.

The third gate electrode pattern GAT3 may include a different material from the first gate electrode pattern GAT1 and the second gate electrode pattern GAT2. The third gate electrode pattern GAT3 may be composed of a different material from the first gate electrode pattern GAT1 and the second gate electrode pattern GAT2 so that a resistance between adjacent wires may be reduced. As a result, the third gate electrode pattern GAT3 and the second gate electrode pattern GAT2 may have different thicknesses. Since the third gate electrode pattern GAT3 is thicker than the second gate electrode pattern GAT2, achieving full etching during the fabrication process can be challenging. As a result, certain regions may retain metallic material that should have been removed during the formation of GAT3.

The present disclosure is designed to solve such a problem.

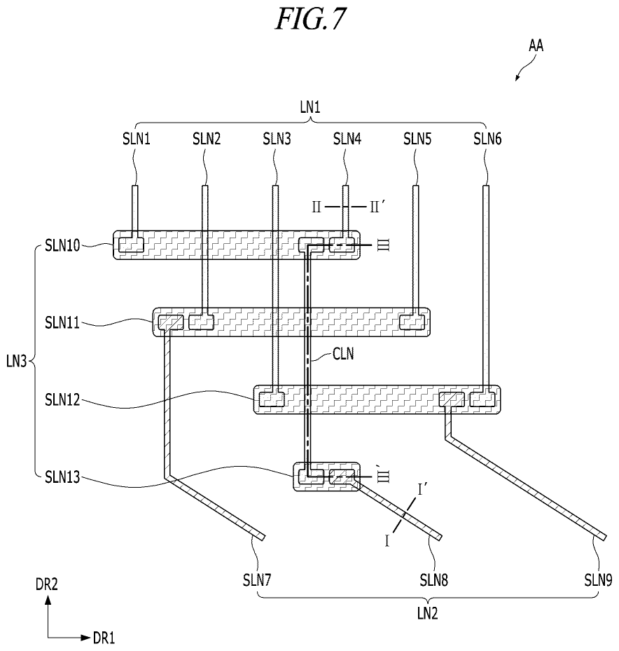

In FIGS. 7, 10A and 11A, which will be explained below, an embodiment and another embodiment of the present invention are applied and illustrated. According to an embodiment and another embodiment of the present invention, a problem due to using different materials for the second gate electrode pattern GAT2 and the third gate electrode pattern GAT3 may be reduced.

Descriptions of the above gate electrode patterns GAT1, GAT2 and GAT3 correspond to an embodiment of the present invention, and a material and a thickness of the gate electrode patterns GAT1, GAT2 and GAT3 may be modified.

At least a portion of scan lines SL (see FIG. 4) and light-emitting control lines ECl (see FIG. 4) may be disposed on at least one of the gate insulating layer GI1, GI2 and GI3.

An interlayer insulating layer ILD covering the third gate electrode pattern GAT3 may be disposed on the third gate insulating layer GI3. The interlayer insulating layer ILD may include an organic film and/or an inorganic film. The interlayer insulating layer ILD may include a plurality of inorganic thin films or organic thin films. The plurality of inorganic thin films may include a silicon nitride layer and a silicon oxide layer. In the present disclosure, the interlayer insulating layer ILD may be referred as a second insulating layer.

At least a portion of the data line DL (see FIG. 4) and the power line PL (see FIG. 4) may be disposed on the interlayer insulating layer ILD. A first source-drain electrode pattern SD1 may be disposed on the interlayer insulating layer ILD. The first source-drain electrode pattern SD1 may include titanium (Ti), aluminum (Al), and titanium (Ti), each disposed in three layers. In an embodiment of the present invention, a thickness of the first source-drain electrode pattern SD1 may be about 6800 Å or less, but the present invention is not limited thereto.

The first via insulating layer VIA1 may be disposed on the first source-drain electrode SD1. The first via insulating layer VIA1 may include an organic film and/or inorganic film. The first via insulating layer VIA1 may provide a flat surface. The first via insulating layer VIA1 may be interposed between an anode electrode AE and the first source-drain electrode pattern SD1. In the present disclosure, the first via insulating layer VIA1 may be referred as a third insulating layer.

A second source-drain electrode pattern SD2 may be disposed on the first via insulating layer VIA1. The second source-drain electrode pattern SD2 may include, for example, titanium (Ti), aluminum (Al) and titanium (Ti), each disposed in three layers. In an embodiment of the present invention, a thickness of the second source-drain electrode pattern SD2 may be about 6800 Å or less, but the present invention is not limited thereto.

A second via insulating layer VIA2 may be disposed on the second source-drain electrode pattern SD2. The second via insulating layer VIA2 may include an organic film and/or inorganic film. The second via insulating layer VIA2 may provide a flat surface. The second via insulating layer VIA2 may be interposed between an anode electrode AE and the second source-drain electrode pattern SD2.

A pixel defining film PDL and a light-emitting diode LD may be disposed on the second via insulating layer VIA2.

The light-emitting diode LD may include an anode electrode AE, a hole control layer HL, a light-emitting layer EML, an electron control layer EL and a cathode electrode CE.

The anode electrode AE may be connected to the first source-drain electrode pattern SD1 through a contact hole penetrating through the via insulating layers VIA1 and VIA2.

An opening part OP defined on the pixel defining film PDL may expose the anode electrode AE.

FIG. 7 is an illustration of a layout corresponding to a section marked with AA shown in FIG. 3.

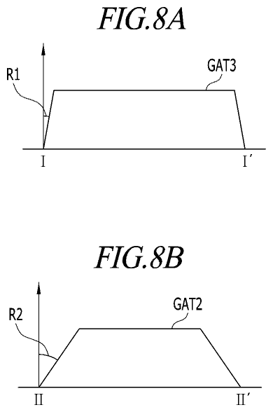

FIG. 8A is an illustration of a portion of a cross-section along the line I-I′ shown in FIG. 7. FIG. 8A is an illustration of a cross-section of a portion of a third gate electrode pattern GAT3.

FIG. 8B is an illustration of a portion of a cross-section along the line II-II′ shown in FIG. 7. FIG. 8B is an illustration of a cross-section of a portion of a second gate electrode pattern GAT2.

According to an embodiment of the present invention, a plane parallel to the base member BL may be disposed below the second gate electrode pattern GAT2 and the third gate electrode pattern GAT3. For example, an upper surface of the base member BL may be disposed below the second gate electrode GAT2. Referring to FIG. 8A, the first angle R1 may be an angle that is formed between a normal line extending from the base member BL and a segment extending from a sidewall of the third gate electrode pattern GAT3. Referring to FIG. 8B, a second angle R2 may be an angle that is formed between a normal line extending from the base member BL and a segment extending from a sidewall of the second gate electrode pattern GAT2. The first angle R1 may be less than the second angle R2. As an example, the first angle R1 may be about 10.2 degrees, and the second angle R2 may be about 34.6 degrees.

The first angle R1 and the second angle R2 may be the above pre-determined angles due to each material property of the second gate electrode pattern GAT2 and the third gate electrode pattern GAT3. When an unnecessary portion of the conductive layer for forming the third gate electrode pattern GAT3 is removed while forming the third gate electrode pattern GAT3, the first angle R1 becomes less due to a materialistic property of titanium (Ti) and aluminum (Al). In addition, when an unnecessary portion of the conductive layer for forming the second gate electrode GAT2 is removed during forming the second gate electrode pattern GAT2, the second angle R2 becomes greater than the first angle R1 due to a materialistic property of molybdenum (Mo).

Values of the first angle R1 and the second angle R2 are described as an example in the present disclosure, but the present invention is not limited thereto. The first angle R1 and the second angle R2 may have other values.

According to embodiments of the present invention, a side of each of the second gate electrode pattern GAT2 and the third gate electrode pattern GAT3 is linear. However, the present invention is not limited to what is illustrated, and a shape of a side of a gate electrode pattern may be modified. For example, a side of each of the second gate electrode pattern GAT2 and the third gate electrode pattern GAT3 may have a pre-determined curved rate.

According to an embodiment of the present invention, a plane parallel to the base member BL may be disposed below the second gate electrode pattern GAT2. A first tangent line, representing a first slope, may be defined by drawing a tangent line from an intersection point that is between the plane parallel to the base member BL and the second gate electrode pattern GAT2.

According to an embodiment of the present invention, a plane parallel to the base member BL may be disposed below the third gate electrode pattern GAT3. A second tangent line, representing a second slope, may be defined by drawing a tangent line from an intersection point that is between the plane parallel to the base member BL and the third gate electrode pattern GAT3.

The first slope may be less than the second slope. Accordingly, a slope of the first tangent line may be less than a slope of the second tangent line.

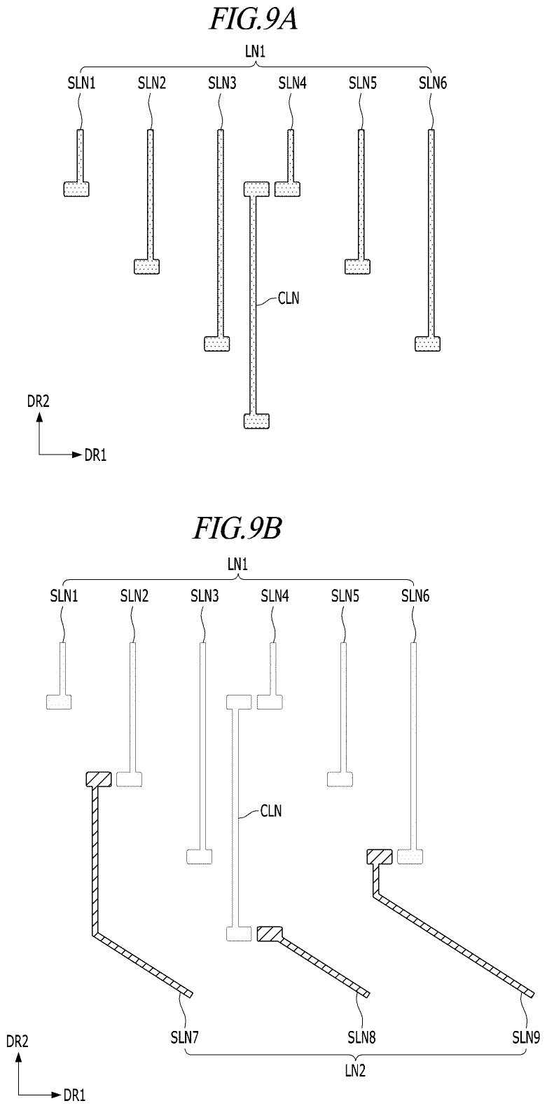

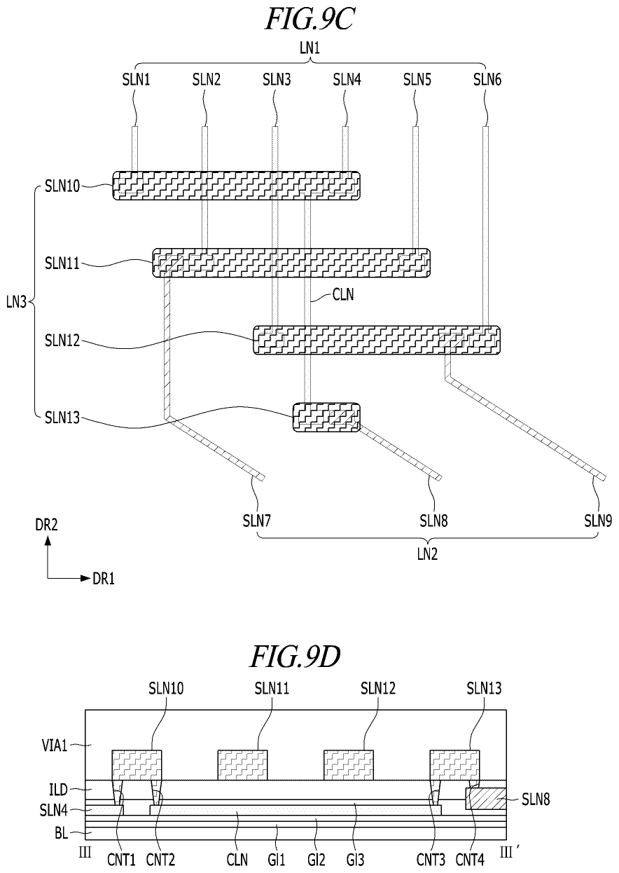

FIG. 9A is an illustration of a partial layout of the second gate electrode pattern GAT2 shown in FIG. 7. The second gate electrode pattern GAT2 may include a plurality of first lines LN1 and a connection line CLN.

According to an embodiment of the present invention, each of the plurality of first lines LN1 may extend in a pre-determined direction. For example, each of the plurality of first lines LN1 may extend in a second direction DR2. The plurality of first lines LN1 may be configured to transfer a data signal to a plurality of pixels PX.

The plurality of pixels PX may include a first green pixel, a first red pixel, a first blue pixel, a second green pixel, a second red pixel and a second blue pixel.

The plurality of first lines LN1 may include a first sub-line through a sixth sub-line SLN1 through SLN6. The first sub-line SLN1 may be disposed at the far left in the first direction DR1 of the plurality of first line LN1, and the second sub-line through the sixth sub-line SLN2 through SLN6 may be successively arranged from the left to the right.

In addition, the connection line CLN may be detachedly disposed from the plurality of first lines LN1. For example, the connection line CLN may be interposed between the third sub-line SLN3 and the fourth sub-line SLN4.

In an embodiment of the present invention, the first sub-line SLN1 may be configured to transfer a data signal to the first green pixel. The second sub-line SLN2 may be configured to transfer a data signal to the first red pixel. The third sub-line SLN3 may be configured to transfer a data signal to the first blue pixel. The fourth sub-line SLN4 may be configured to transfer a data signal to the second green pixel. The fifth sub-line SLN5 may be configured to transfer a data signal to the second red pixel, and the sixth sub-line SLN6 may be configured to transfer a data signal to the second blue pixel. The connection line CLN may be configured to transfer a data signal to the first green pixel and the second green pixel through the first sub-line SLN1 and the fourth sub-line SLN4, respectively.

A description of a specific process for transferring a data signal is as follows. Each of the plurality of first lines LN1 may be configured to transfer a data signal to the demultiplexer DMX, and the demultiplexer DMX may be configured to transfer the received data signal to a corresponding pixel among the plurality of pixels PX.

FIG. 9B is an illustration of a plurality of second lines LN2 in the third gate electrode pattern GAT3. The third gate electrode pattern GAT3 may include a plurality of second lines LN2. FIG. 9B is an illustration further including a plurality of second lines LN2, which is not included in FIG. 9A.

The plurality of second lines LN2 may be configured to receive a data signal from the data driving circuit DIC and transfer the signal to plurality of first lines LN1.

The plurality of second lines LN2 may include a seventh sub-line through a nineth sub-line SLN7 through SLN9. The seventh sub-line SLN7 may be disposed in the far left in the first direction DR1 of the plurality of second lines LN2, and the eighth sub-line and the nineth sub-line SLN8 and SLN9 may be successively disposed from the left to the right.

In an embodiment of the present invention, the seventh sub-line SLN7 may be configured to transfer a data signal to the first red pixel through the second sub-line SLN2 and the fifth sub-line SLN5. The eighth sub-line SLN8 may be configured to transfer a data signal to the second green pixel through the connection line CLN, the first sub-line SLN1 and the fourth sub-line SLN4.The nineth sub-line SLN9 may be configured to transfer a data signal to the second blue pixel through the third sub-line SLN3 and the sixth sub-line SLN6.

FIG. 9C is an illustration of a plurality of third lines LN3 to the first source-drain electrode pattern SD1. The first source-drain electrode pattern SD1 may include a plurality of third lines LN3. FIG. 9C is an illustration further including a plurality of third lines LN3, which FIG. 9B does not include.

According to an embodiment of the present invention, each of the plurality of third lines LN3 may extend in a direction intersecting with the plurality of first lines LN1 shown in FIG. 9A. For example, each of the plurality of third lines LN3 may extend in the first direction DR1. The plurality of third lines LN3 may include a tenth sub-line through a thirteenth sub-line SLN10 through SLN13. The tenth sub-line SLN10 may be disposed uppermost in the second direction DR2 of the plurality of third lines LN3, and the eleventh sub-line through the thirteenth sub-line SLN11 through SLN13 may be successively disposed from the top to the bottom.

The tenth sub-line SLN10 may be configured to electrically connect the first sub-line SLN1 and the fourth sub-line SLN4 to each other.

The eleventh sub-line SLN11 may be configured to electrically connect the second sub-line SLN2 and the fifth sub-line SLN5 to each other.

The twelfth sub-line SLN12 may be configured to electrically connect the third sub-line SLN3 and the sixth sub-line SLN6 to each other.

The thirteenth sub-line SLN13 may be configured to electrically connect the connection line CLN to the eighth sub-line SLN8.

The connection line CLN may be configured to electrically connect the tenth sub-line SLN10 and the thirteenth sub-line SLN13 to each other.

FIG. 9D is an illustration of a portion of a cross-section taken along the line III-III′ shown in FIG. 7.

In comparison of elements shown in FIG. 9D with elements shown in FIG. 6, an element having the same figure numeral may be an element formed through a same process.

In addition, a referred term may be different for convenience in the present disclosure. A description that is identical to the description for FIG. 6 may therefore be omitted.

According to an embodiment of the present invention, a plurality of contact holes CNT1 through CNT4 may be defined on the interlayer insulating layer ILD. The plurality of contact holes CNT1 through CNT4 may include a first contact hole CNT1, a second contact hole CNT2, a third contact hole CNT3 and a fourth contact hole CNT4.

The first contact hole CNT1 may overlap with any one of the plurality of third lines LN3 and a portion of the plurality of first lines LN1. For example, the first contact hole CNT1 may overlap with each of the tenth sub-line SLN10 and the fourth sub-line SLN4. For example, the first contact hole CNT1 may be disposed between the tenth sub-line SLN10 and the fourth sub-line SLN4. The fourth sub-line SLN4 and the tenth sub-line SLN10 may be electrically connected to each other through the first contact hole CNT1.

The second contact hole CNT2 may overlap with any one of the plurality of third lines LN3 and the connection line CLN. For example, the second contact hole CNT2 may overlap with the tenth sub-line SLN10 and the connection line CLN. For example, the second contact hole CNT2 may be disposed between the tenth sub-line SLN10 and the connection line CLN. The tenth sub-line SLN10 and the connection line CLN may be electrically connected to each other through the second contact hole CNT2.

The third contact hole CNT3 may overlap with the connection line CLN and another of the plurality of third lines LN3. For example, the third contact hole CNT3 may overlap with the connection line CLN and the thirteenth sub-line SLN13. The third contact hole CNT3 may be disposed between the connection line CLN and the thirteenth sub-line SLN13. The connection line CLN and the thirteenth sub-line SLN13 may be electrically connected to each other through the third contact hole CNT3.

The fourth contact hole CNT4 may overlap with another of the plurality of third lines LN3 and a portion of the plurality of second lines LN2. For example, a fourth contact hole CNT4 may overlap with the thirteenth sub-line SLN13 and the eighth sub-line SLN8. For example, the fourth contact hole CNT4 may be disposed between the thirteenth sub-line SLN13 and the eighth sub-line SLN8. The thirteenth sub-line SLN13 and the eighth sub-line SLN8 may be electrically connected to each other through the fourth contact hole CNT4.

Accordingly, a data signal may be transmitted to a corresponding pixel among the plurality of pixels PX through electrically connected lines that are connected to each other through the first contact hole CNT1, the second contact hole CNT2, the third contact hole CNT3 and the fourth contact hole CNT4.

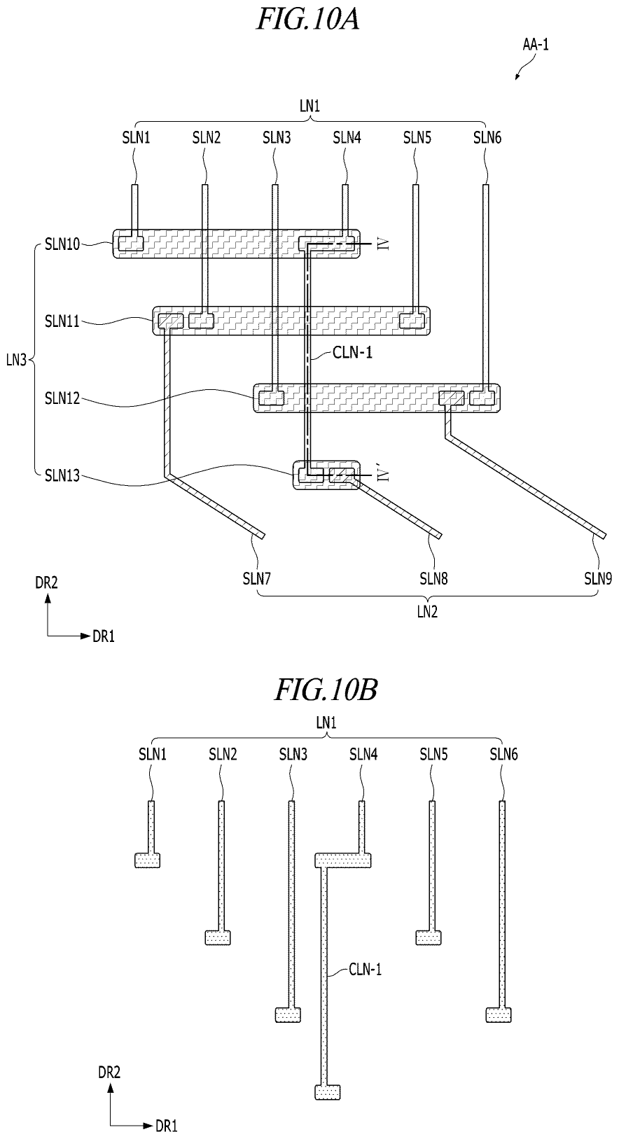

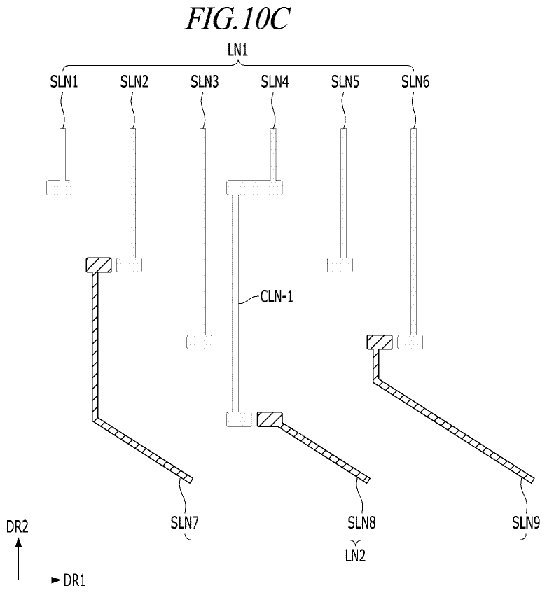

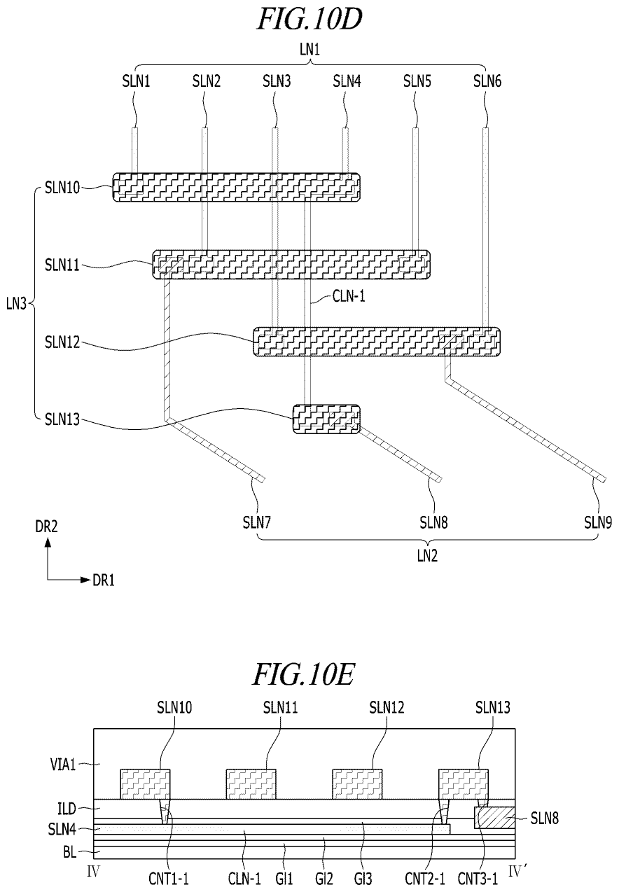

FIG. 10A is an illustration of an embodiment of a layout corresponding to a section marked with AA shown in FIG. 3.

FIG. 10B is an illustration of a plurality of first lines LN1 and a connection line CLN-1 in the second gate electrode pattern GAT2. The second gate electrode pattern GAT2 may include the plurality of first lines LN1 and the connection line CLN-1.

In FIG. 10B, the fourth sub-line SLN4 and the connection line CLN-1 may contact each other. For example, the fourth sub-line SNL4 and the connection line CNL-1 may be a single integrated body. Other descriptions that are substantially the same as the above description for FIG. 9A may be omitted to avoid redundancy.

FIG. 10C is an illustration of a plurality of second lines LN2 in the third gate electrode pattern GAT3. The third gate electrode pattern GAT3 may include the plurality of second lines LN2. FIG. 10C is an illustration that further includes a plurality of second lines LN2, which FIG. 10B does not include. Hereinafter, a detailed description about FIG. 10C is substantially the same as the above description for FIG. 9B, and therefore may be omitted.

FIG. 10D is an illustration of a plurality of third lines LN3 of the first source-drain electrode pattern SD1. The first source-drain electrode pattern SD1 may include a plurality of third lines LN3. FIG. 10D is an illustration with addition of a plurality of third lines LN3. Hereinafter, a detailed description about FIG. 10D is substantially the same as the above description for FIG. 9C, and therefore may be omitted.

FIG. 10E is an illustration of a portion of a cross-section along the line IV-IV′ shown in FIG. 10A.

In the present disclosure, a definition of a lamination structure and a term is substantially the same as the description for FIG. 6, and therefore may be omitted.

According to an embodiment of the present invention, a plurality of contact holes CNT1 through CNT3 may be defined on the interlayer insulating layer ILD. The plurality of contact holes CNT1 through CNT3 may include a first contact hole CNT1-1, a second contact hole CNT2-1 and a third contact hole CNT3-1.

A first contact hole CNT1-1 may overlap with any one of the plurality of third lines LN3 and a connection line CLN-1. For example, the first contact hole CNT1-1 may overlap with the tenth sub-line SLN10 and a fourth sub-line SLN4, or with the tenth sub-line SLN10 and the connection line CLN-1. In addition, the fourth sub-line SLN4 and the connection line CLN-1 may contact each other. The fourth sub-line SLN4 and the tenth sub-line SLN10 may be electrically connected to each other through the first contact hole CNT1-1.

The second contact hole CNT2-1 may overlap with the connection line CLN-1 and the plurality of third lines LN3. For example, the second contact hole CNT2-1 may overlap with the connection line CLN-1 and the thirteenth sub-line SLN13. The connection line CLN-1 and the thirteenth sub-line SLN13 may be electrically connected to each other through the second contact hole CNT2-1.

The third contact hole CNT3-1 may overlap with another of the plurality of third lines LN3 and a portion of the plurality of second lines LN2. For example, the third contact hole CNT3-1 may overlap with the thirteenth sub-line SLN13 and the eighth sub-line SLN8. The thirteenth sub-line SLN13 and the eighth sub-line SLN8 may be electrically connected to each other through the third contact hole CNT3-1.

Accordingly, a data signal may be transferred to a corresponding pixel among the plurality of pixels PX through lines electrically connected through the first contact hole CNT1-1, the second contact hole CNT2-1 and the third contact hole CNT3-1.

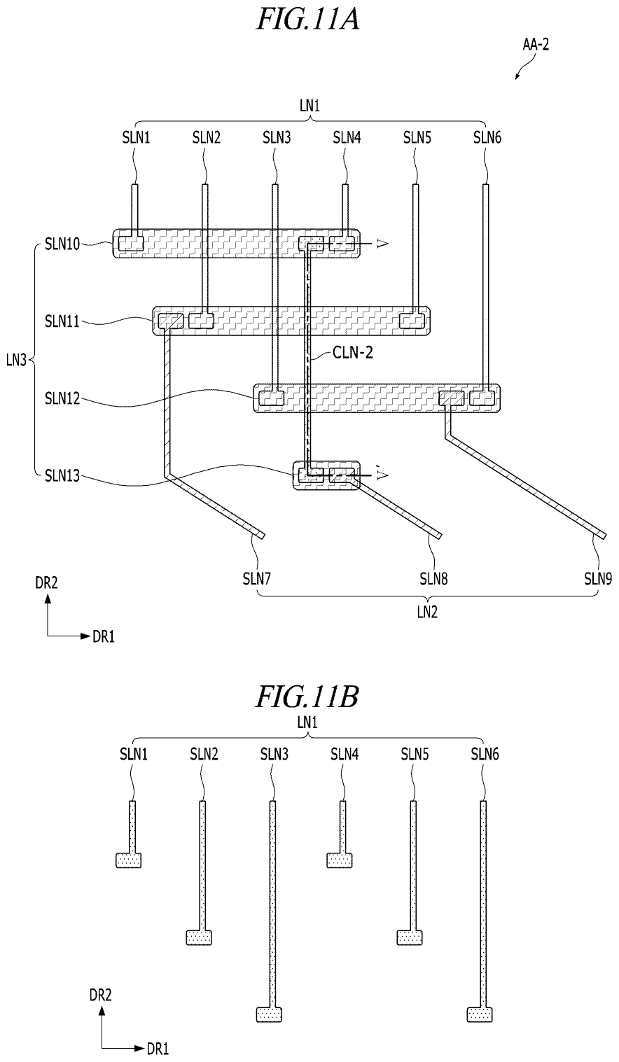

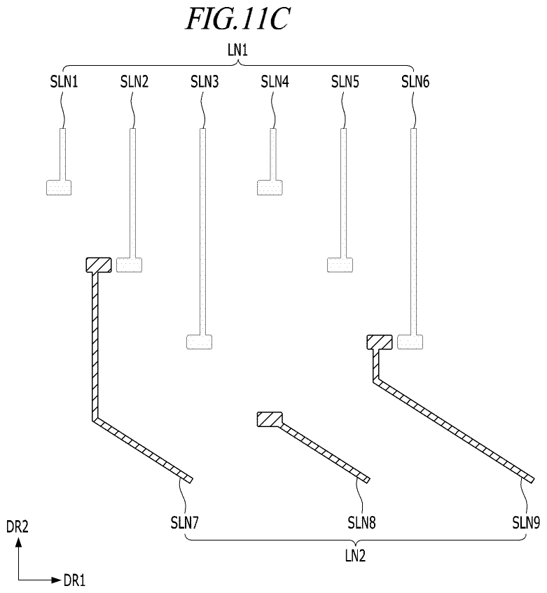

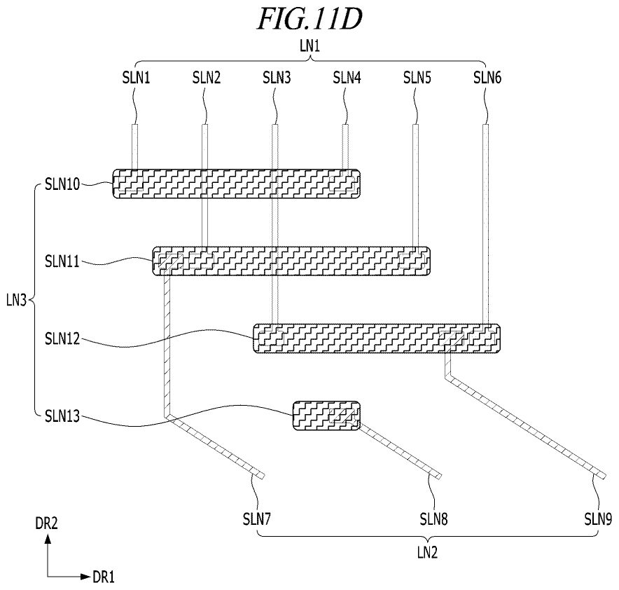

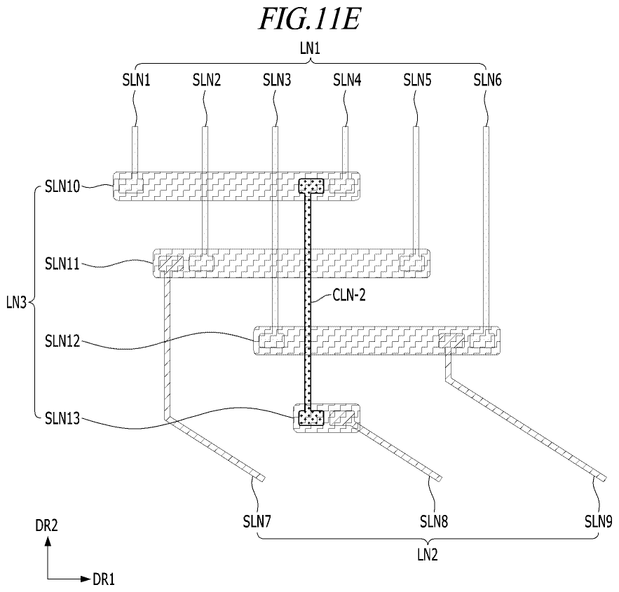

FIG. 11A is an illustration of an embodiment of a layout corresponding to a section marked with AA shown in FIG. 3.

FIG. 11B is an illustration of a plurality of first lines LN1 in the second gate electrode pattern GAT2. The second gate electrode pattern GAT2 may include a plurality of first lines LN1. A difference from FIG. 10B is that the second gate electrode pattern GAT2 includes the plurality of first lines LN1 and does not include the connection line CLN-1 in FIG. 11B. Hereinafter, a detailed description about FIG. 11B is substantially the same as the above description for FIG. 9A, and therefore may be omitted.

FIG. 11C is an illustration merely of a plurality of second lines LN2 in the third gate electrode pattern GAT3. The third gate electrode pattern GAT3 may include a plurality of second lines LN2. FIG. 11C is an illustration further including the plurality of second lines LN2, which is not included in FIG. 11B. Hereinafter, a detailed description about FIG. 11C is substantially the same as the above description for FIG. 9B, and therefore may be omitted.

FIG. 11D is an exemplary illustration merely of a plurality of third lines LN3 in the first source-drain electrode pattern SD1. The first source-drain electrode pattern SD1 may include the plurality of third lines LN3. FIG. 11D is an illustration further including the plurality of third lines LN3, which is not included in FIG. 11C. Hereinafter, a detailed description about FIG. 11D is substantially the same as the above description for FIG. 9C, and therefore may be omitted.

FIG. 11E is an illustration merely of a connection line CLN-2 of the second source-drain electrode pattern SD2. The second source-drain electrode pattern SD2 may include the connection line CLN-2. FIG. 11E is an illustration further including the connection line CLN-2, which is not included in FIG. 11D. The connection line CLN-2 may electrically connect the tenth sub-line SLN10 and the thirteenth sub-line SLN13 to each other.

FIG. 11F is an illustration of a portion of a cross-section taken along the line V-V′ of FIG. 11A. In the present disclosure, a definition of a lamination structure and a term is substantially the same as the above description for FIG. 6, and therefore may be omitted.

Referring to FIG. 11F, a first contact hole CNT1-2 and a second contact hole CNT2-2 may be defined on the interlayer insulating layer ILD. In addition, a third contact hole CNT3-2 and a fourth contact hold CNT4-2 may be formed in the first via insulating layer VIA1.

The first contact hole CNT1-2 may overlap with any one of the plurality of third lines LN3 and any one of the plurality of first lines LN1. For example, the first contact hole CNT1-2 may overlap with the tenth sub-line SLN10 and the fourth sub-line SLN4. For example, the first contact hole CNT1-2 may be disposed between the tenth sub-line SLN10 and the fourth sub-line SLN4. The fourth sub-line SLN4 and the tenth sub-line SLN10 may be electrically connected to each other through the first contact hole CNT1-2.

The second contact hole CNT2-2 may overlap with another of the plurality of third lines LN3 and any one of the plurality of second lines LN2. For example, the second contact hole CNT2-2 may overlap with the thirteenth sub-line SLN13 and the eighth sub-line SLN8. For example, the second contact hole CNT2-2 may be disposed between the thirteenth sub-line SLN13 and the eighth sub-line SLN8. The thirteenth sub-line SLN13 and the eighth sub-line SLN8 may be electrically connected to each other through the second contact hole CNT2-2.

The third contact hole CNT3-2 may overlap with any one of the plurality of third lines LN3 and the connection line CLN-2. For example, the third contact hole CNT3-2 may overlap with the tenth sub-line SLN10 and the connection line CLN-2. For example, the third contact hole CNT3-2 may be disposed between the tenth sub-line SLN10 and the connection line CLN-2. The tenth sub-line SLN10 and the connection line CLN-2 may be electrically connected to each other through the third contact hole CNT3-2.

The fourth contact hole CNT4-2 may overlap with the connection line CLN-2 and another of the plurality of third lines LN3. For example, the fourth contact hole CNT4-2 may overlap with the connection line CLN-2 and the thirteenth sub-line SLN13. For example, the fourth contact hole CNT4-2 may be disposed between the connection line CLN-2 and the thirteenth sub-line SLN13. The connection line CLN-2 and the thirteenth sub-line SLN13 may be electrically connected to each other through the fourth contact hole CNT4-2.

Accordingly, a data signal may be transmitted to a corresponding pixel among the plurality of pixels through lines that are electrically connected to each other through the first contact hole CNT1-2, the second contact hole CNT2-2, the third contact hole CNT3-2 and the fourth contact hole CNT4-2.

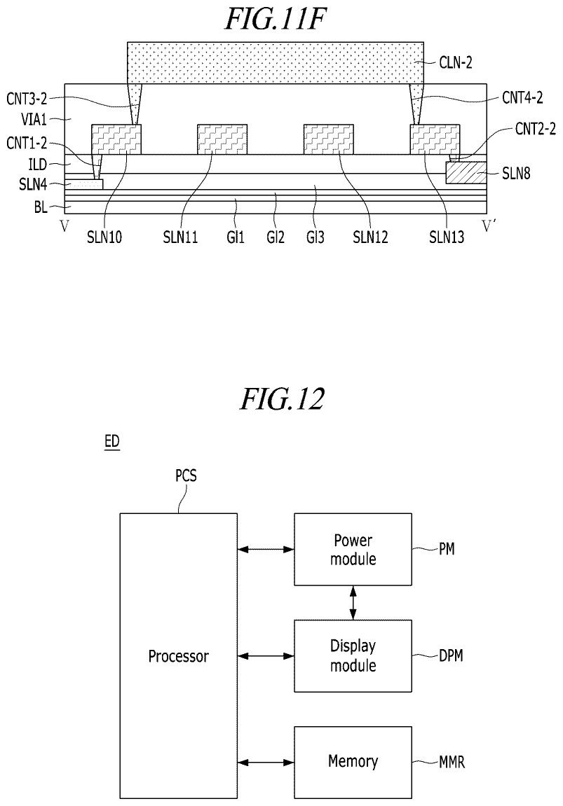

FIG. 12 is an exemplary block diagram of an electronic device according to an embodiment of the present invention.

Referring to FIG. 12, the electronic device ED according to an embodiment of the present invention may include a display module DPM, a processor PCS, a memory MMR, and a power module PM.

The processor PCS may include at least one of a central processing unit CPU, an application processor AP, a graphic processing unit GPU, a communication processor CP, an image signal processor ISP, and a controller.

The memory MMR may be configured to store data information for operation of the processor PCS or the display module DPM. In the case that the processor PCS operates an application stored in the memory MMR, the display module DPM may be configured to receive an image data signal and/or an input control signal and process the received signal to provide an output of image information through a display screen.

A power module PM may include a power supply module, such as a power adapter or a battery device, and a power conversion module, which converts power supplied by the power supply module to generate power for operation of an electronic device ED.

At least one of the elements of the above electronic device ED may be included in the display device according to the above embodiments of the present invention. In addition, some of individual modules functionally included in a single module may be included in the display device, and the other may be provided separately from the display device. For example, a display module may be included in the display device, and the processor PCS, the memory MMR, and the power module PM may be provided in a form of another device within the electronic device ED other than the display device.

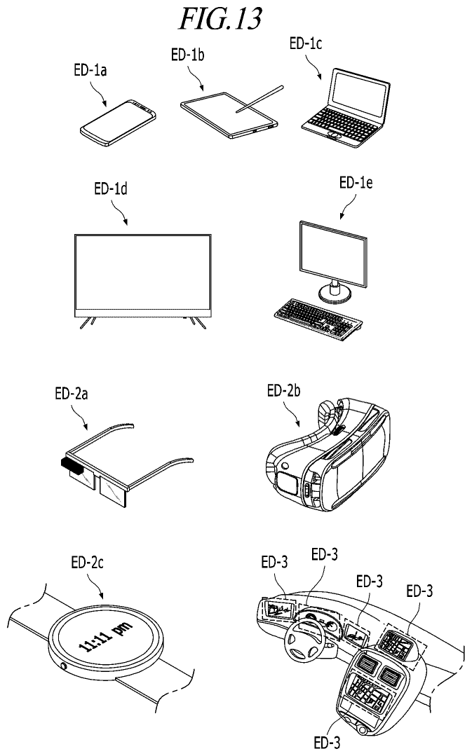

FIG. 13 illustrates schematic diagrams of electronic devices according to embodiments of the present invention.

Referring to FIG. 13, various electronic devices having display devices according to embodiments of the present invention may include not only an electronic device configured to display an image, such as a smart phone ED-1a, a tablet PC ED-1b, a laptop ED-1c, a TV ED-1d, and a desk monitor ED-1e, but also a wearable electronic device including a display module, such as smart glass ED-2a, a head mounted display ED-2b, and a smart watch ED-2c, and a vehicle electronic device ED-3 including a display module, such as a CID (Center Information Display) and a room mirror display disposed on an instrument panel, center fascia, and a dashboard of an automobile.

While the present invention has been described with reference to exemplary embodiments thereof, it will be understood by those of ordinary skill in the art that various changes in form and details may be made thereto without departing from the spirit and scope of the present invention.

What is claimed is:

1. A display panel comprising:
a base member including a first region and a second region at least partially surrounding the first region;
a plurality of pixels disposed on the first region;
a plurality of first lines disposed on the second region and configured to transfer an electrical signal to the plurality of pixels, wherein each of the plurality of first lines extend in a pre-determined direction;
a first insulating layer covering the plurality of first lines;
a second line disposed on the first insulating layer;
a second insulating layer disposed on the first insulating layer and covering the second line;
a plurality of third lines disposed on the second insulating layer, wherein each of the plurality of third lines extend in a direction that intersects with the pre-determined direction,
wherein at least one of the plurality of third lines overlaps with the plurality of first lines;
a third insulating layer disposed on the second insulating layer and covering the plurality of third lines; and
a connection line extending in the pre-determined direction, and overlapping with the at least one of the plurality of third lines, wherein the connection line is configured to electrically connect a portion of the plurality of first lines and the second line to each other.

2. The display panel of claim 1,
wherein each of the plurality of first lines has a first thickness, and the second line has a second thickness, which is greater than the first thickness.

3. The display panel of claim 2,
wherein each of the plurality of first lines comprises a first metallic material, and the second line comprises a second metallic material, which is different from the first metallic material.

4. The display panel of claim 3,
wherein the first metallic material comprises molybdenum (Mo), and the second metallic material comprises at least one of titanium (Ti) or aluminum (Al).

5. The display panel of claim 1,
wherein the connection line is disposed below the first insulating layer.

6. The display panel of claim 5,
wherein the second insulating layer is defined with a first contact hole, a second contact hole, a third contact hole and a fourth contact hole,
wherein the first contact hole overlaps with one of the plurality of third lines and the portion of the plurality of first lines,
wherein the second contact hole overlaps with the one of the plurality of third lines and the connection line,
wherein the third contact hole overlaps with another of the plurality of third lines and the connection line, and
wherein the fourth contact hole overlaps with the other of the plurality of third lines and the second line.

7. The display panel of claim 5,
wherein the second insulating layer is defined with a first contact hole, a second contact hole and a third contact hole, and the connection line overlaps with the portion of the plurality of first lines,
wherein the first contact hole overlaps with one of the plurality of third lines,
wherein the first contact hole overlaps with the connection line or the portion of the plurality of first lines,
wherein the second contact hole overlaps with another of the plurality of third lines and the connection line, and
wherein the third contact hole overlaps with the other of the plurality of third lines and the second line.

8. The display panel of claim 4,
wherein the connection line is disposed on the third insulating layer.

9. The display panel of claim 8,
wherein the second insulating layer is defined with a first contact hole and a second contact hole,
wherein the third insulating layer is defined with a third contact hole and a fourth contact hole,
wherein the first contact hole overlaps with one of the plurality of third lines and the portion of the plurality of first lines,
wherein the second contact hole overlaps with another of the plurality of third lines and the second line,
wherein the third contact hole overlaps with the connection line and the oneof the plurality of third lines, and
wherein the fourth contact hole overlaps with the connection line and the otherof the plurality of third lines.

10. The display panel of claim 4, further comprising:
a data driving circuit disposed on the second region; and
a demultiplexer configured to receive a data signal from the data driving circuit and provide the received data signal to the plurality of pixels, wherein the demultiplexer is interposed between the data driving circuit and the first region,
wherein at least one of the plurality of first lines, the second line, the plurality of third lines or the connection line is interposed between the data driving circuit and the demultiplexer.

11. The display panel of claim 4,
wherein an angle that is between a segment corresponding to a side of the second line and a normal line of the base member is less than any angle that is between a segment corresponding to a side of each of the plurality of first lines and the normal line.

12. An electronic device comprising:
a base member;
a semiconductor pattern disposed on the base member;
a first gate insulating layer disposed on the semiconductor pattern;
a first gate electrode pattern disposed on the first gate insulating layer and having at least a portion overlapping with the semiconductor pattern;
a second gate insulating layer disposed on the first gate electrode pattern;
a second gate electrode pattern disposed on the second gate insulating layer;
a third gate insulating layer disposed on the second gate electrode pattern;
a third gate electrode pattern disposed on the third gate insulating layer and having a greater thickness than the second gate electrode pattern;
an interlayer insulating layer disposed on the third gate electrode pattern;
a first source-drain electrode pattern disposed on the interlayer insulating layer;
a first via insulating layer disposed on the first source-drain electrode pattern; and
a second source-drain electrode pattern disposed on the first via insulating layer,
wherein the second gate electrode pattern comprises a plurality of first lines, each of which extends in a pre-determined direction,
wherein the third gate electrode pattern comprises a second line,
wherein the first source-drain electrodes comprises a plurality of third lines of which at least one is configured to electrically connect two non adjacent first lines among the plurality of first lines,
wherein one of the second gate electrode pattern or the second source-drain electrode comprises a connection line extending in the pre-determined direction, and
wherein the connection line overlaps with at least one of the plurality of third lines and configured to electrically connect a portion of the plurality of first lines and the second line to each other.

13. The electronic device of claim 12, further comprising:
a second via insulating layer disposed on the second source-drain electrode pattern; and
a light-emitting diode disposed on the second via insulating layer and comprising an anode electrode, a light-emitting layer and a cathode electrode.

14. The electronic device of claim 13,
wherein the second gate electrode pattern comprises molybdenum (Mo), and
wherein the third gate electrode pattern comprises at least one of titanium (Ti) or aluminum (Al).

15. The electronic device of claim 14,
wherein a first tangent line extends from an intersection point that is between the second gate electrode pattern on a plane parallel and the base member,
wherein a second tangent line extends from an intersection point that is between the third gate electrode pattern on a plane parallel and the base member, and
wherein a slope of the first tangent line is less than a slope of the second tangent line.

16. The electronic device of claim 14,
wherein the connection line is disposed below the third gate insulating layer.

17. The electronic device of claim 16,
wherein the interlayer insulating layer is defined with a first contact hole, a second contact hole, a third contact hole and a fourth contact hole,
wherein the first contact hole overlaps with one of the plurality of third lines and the portion of the plurality of first lines,
wherein the second contact hole overlaps with the one of the plurality of third lines and the connection line,
wherein the third contact hole overlaps with another of the plurality of third lines and the connection line, and
wherein the fourth contact hole overlaps with the other of the plurality of third lines and the second line.

18. The electronic device of claim 16,
wherein the interlayer insulating layer is defined with a first contact hole, a second contact hole and a third contact hole,
wherein the connection line contacts the portion of the plurality of first lines,
wherein the first contact hole overlaps with one of the plurality of third lines, and the first contact hole overlaps with the connection line or the portion of the plurality of first lines,
wherein the second contact hole overlaps with another of the plurality of third lines and the connection line, and
wherein the third contact hole overlaps with the other of the plurality of third lines and the second line.

19. The electronic device of claim 14,
wherein the connection line is disposed on the first via insulating layer.

20. The electronic device of claim 19,
wherein the interlayer insulating layer is defined with a first contact hole and a second contact hole,
wherein the first via insulating layer is defined with a third contact hole and a fourth contact hole,
wherein the first contact hole overlaps with one of the plurality of third lines and the portion of the plurality of first lines,
wherein the second contact hole overlaps with another of the plurality of third lines and the second line,
wherein the third contact hole overlaps with the one of the plurality of third lines and the connection line, and
wherein the fourth contact hole overlaps with the other of the plurality of third lines and the connection line.
